(19) United States
(12) Patent Application Publication
(10) Pub. No.: US 2011/0286061 A1
(43) Pub. Date: Nov. 24, 2011

(54) SMART MODE COLOR WORKFLOW

(75) Inventors: Barry Ayash, Webster, NY (US); Kevin St. Martin, Webster, NY (US); David Jarvis, Webster, NY (US)

(73) Assignee: Xerox Corporation

(21) Appl. No.: 12/784,339

(22) Filed: May 20, 2010

(51) Int. Cl. G03F 3/08

(52) U.S. Cl. 358/518

(57) ABSTRACT

A technique for achieving optimal color quality in rendered print jobs using a smart mode color workflow is disclosed. A smart mode color workflow provides for a pre-flight check of a print job to determine the job's relevant color attributes. Only relevant color attributes are displayed for review and selection during color transformation of the print job. All irrelevant color attributes are either grayed-out or not displayed to prevent an inexperienced user from selecting irrelevant color attributes during a color transformation. Providing only relevant color attributes for selection allows a user to become more efficient in achieving optimal color quality in a color transformation for a final rendered document.

### TECHNICAL FIELD

Embodiments are related to rendering devices, techniques and image-processing methods and systems. Embodiments are further related to color rendering technology. Embodiments are additionally related to a color transformation workflow utilized in color rendering.

### BACKGROUND OF THE INVENTION

Color quality transformations modify a print job's color attributes to produce optimal color in rendering of that print job. Complex color transformations utilized in color rendering applications, however, often result in non-optimal color quality results, as most color transformations options are selected by a user, thus leaving room for human error. A user who selects color transformations may lack the proper training required to make appropriate selections to produce optimal color quality in a rendering. Further, a user may be unfamiliar with the creation and rendering requirements of a specific job. An inexperienced user may not have the necessary knowledge to properly transform a job's gamut range, either within a single color space such as, for example, CMYK, RGB, spot color, gray, or black, or between the RGB to CMYK color spaces. The user may be unsure as to how different color transformations affect rendering when converting between each gamut. Finally, the user may be unaware if the print job to be rendered contains Pantones®, thus requiring a higher level of experience for a user to perform a proper color transformation for optimal color quality.

These color transformations may be performed on a print job in the digital front end (DFE) of an image output or destination device. The DFE may include a raster image processor (RIP), such as for a digital color press to convert a high-level page description language, such as, for example, Adobe® PostScript® or portable document format (PDF), into raster images. A user's uniformed color management selections in the DFE may produce inconsistent print job rendering results across a number of devices. Manual adjustment of CMYK combinations, without any guidance provided to a user by a pre-flight check for accurate color management selections may result in variability when a job is rendered from different output devices. Output devices use device-specific color profiles that define the boundaries of that device's gamut. The color profile of one device may differ considerably from the color profile of another device. Therefore, an unguided user may spend vast amounts of time in repeated color transformation trials when trying to achieve optimal color quality between devices with differing device-specific color profiles. For example, when a user is printing a proof on a device before a press printing of a final print job on another device, it is vital to establish a close color match between the devices to ensure the optimal color quality of the final print job.

To guarantee optimal color quality in rendered print jobs, a user needs to be informed of a print job's relevant color attributes for the user to properly perform color transformations on that job. Some current color transformation workflows display a print job's color attributes for selection during a color transformation. However, none of those selections are controlled by the information gathered during a workflow's pre-flight check of the print job. A pre-flight check provides a user with relevant color attribute selection information for specific color transformation options within a print job. If only valid color transformation selections, as controlled and determined by a pre-flight check, are displayed for a user to select for optimal color quality, then a user would be more informed when deciding on proper color transformations. Displaying only relevant color attribute selections for a user to select will result in higher quality color transformations in renderings, as users with differing levels of experience are provided with only relevant color transformation selections. Therefore, a need exists for a technique to provide a user with relevant color transformation selections for a print job to assist a user in producing consistent, high quality, color renderings.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for improved rendering devices, techniques and image-processing methods and systems.

It is another aspect of the present invention to provide for an improved color rendering technology.

It is a further aspect of the present invention to provide for a more functional and efficient color transformation workflow utilized in color rendering by providing only relevant color attribute selections as controlled and determined by a pre-flight check.

The aforementioned aspects and other objectives and advantages can now be achieved as described herein. This solution expands on the above functions to include a workflow for providing a relevant color attribute selection display for a print job. The relevant color attributes are determined and controlled by a pre-flight check. Additionally, irrelevant color attributes for a print job are either grayed-out, or not shown, to provide a user with an informed choice for selecting appropriate color attributes when performing a color transformation on a print job. Accordingly, relevant color attributes for a print job can be used to provide a user with appropriate choices for achieving optimal color quality in a rendered print job.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a block diagram of a data-processing apparatus, which can be utilized for adding processes to print production workflows, in accordance with a preferred embodiment;

FIG. 2 illustrates an exemplary graphical user interface (GUI) for display of relevant color transformation selections for a print job as determined in a pre-flight print job check, in accordance with a preferred embodiment of the present invention; and

FIG. 3 illustrates a block diagram of the overall smart mode color workflow for a print job, in accordance with a preferred embodiment.

### DETAILED DESCRIPTION

The particular values and configurations discussed in these non-limiting examples can be varied and are cited merely to illustrate at least one embodiment and are not intended to limit the scope thereof.

The embodiments described herein can be implemented in the context of a host operating system and one or more modules. Such modules may constitute hardware modules, such as, for example, electronic components of a computer system. Such modules may also constitute software modules. In the computer programming arts, a software “module” can be typically implemented as a collection of routines and data structures that performs particular tasks or implements a particular abstract data type.

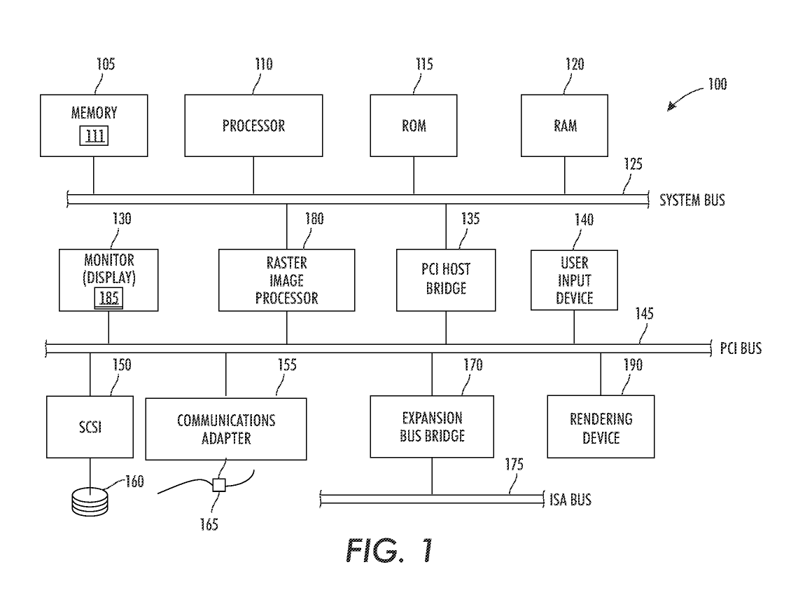

Software modules generally can include instruction media storable within a memory location of an image processing apparatus and are typically composed of two parts. First, a software module may list the constants, data types, variable, routines and the like that can be accessed by other modules or routines. Second, a software module can be configured as an implementation, which can be private (i.e., accessible perhaps only to the module), and that contains the source code that actually implements the routines or subroutines upon which the module is based. The term “module” as utilized herein can therefore generally refer to software modules or implementations thereof. Such modules can be utilized separately or together to form a program product that can be implemented through signal-bearing media, including transmission media and/or recordable media. An example of such a module that can embody features of the present invention is module 111 depicted in FIG. 1.

It is important to note that, although the embodiments are described in the context of a fully functional data-processing system (e.g., a computer system), those skilled in the art will appreciate that the mechanisms of the embodiments are capable of being distributed as a program product in a variety of forms, and that the present invention applies equally regardless of the particular type of signal-bearing media utilized to actually carry out the distribution. Examples of signal bearing media include, but are not limited to, recordable-type media such as media storage or CD ROMs and transmission-type media such as analogue or digital communications links.

Referring to FIG. 1, illustrated is a data-processing apparatus 100 which can be utilized for providing a user with relevant color transformation selections for a print job, such selections controlled by a pre-flight check within a smart mode color workflow. Data-processing apparatus 100 represents one of many possible data-processing and/or computing devices, which can be utilized in accordance with the disclosed embodiments. It can be appreciated that data-processing apparatus 100 and its components are presented for generally illustrative purposes only and do not constitute limiting features of the disclosed embodiments.

As depicted in FIG. 1, a memory 105, a processor (CPU) 110, a Read-Only memory (ROM) 115, and a Random-Access Memory (RAM) 120 are generally connected to a system bus 125 of data-processing apparatus 100. Memory 105 can be implemented as a ROM, RAM, a combination thereof, or simply a general memory unit. Module 111 includes software module in the form of routines and/or subroutines for carrying out features of the present invention and can be additionally stored within memory 105 and then retrieved and processed via processor 110 to perform a particular task. A user input device 140, such as a keyboard, mouse, or another pointing device, can be connected to PCI (Peripheral Component Interconnect) bus 145. Module 111 can be adapted for providing a graphical user interface 200 and processing the smart mode color workflow for a print job. Processor 110 can be adapted to process said workflow pre-flight check to determine and present only relevant print job color attributes for user selection during a color transformation.

Data-process apparatus 100 can thus include CPU 110, ROM 115, RAM 120, and a rendering device 190 (e.g., printer, copier, scanner, xerography equipment etc.), which are also coupled to a PCI (Peripheral Component Interconnect) local bus 145 of data-processing apparatus 100 through PCI host-bridge 135. The PCI Host Bridge 135 can provide a low latency path through which processor 110 may directly access PCI devices mapped anywhere within bus memory and/or input/output (I/O) address spaces. PCI Host Bridge 135 also can provide a high bandwidth path for allowing PCI devices to directly access RAM 120.

A communications adapter 155, a small computer system interface (SCSI) 150, a raster image processor (RIP) 180, and an expansion bus-bridge 170 can also be attached to PCI local bus 145. The communications adapter 155 can be utilized for connecting data-processing apparatus 100 to a network 165. SCSI 150 can be utilized to control high-speed SCSI disk drive 160. An expansion bus-bridge 170, such as a PCI-to-ISA bus bridge, may be utilized for coupling ISA bus 175 to PCI local bus 145. Note that PCI local bus 145 can further be connected to a monitor 130, which functions as a display (e.g., a video monitor) for displaying data and information for a user and also for interactively displaying a graphical user interface (GUI) 200.

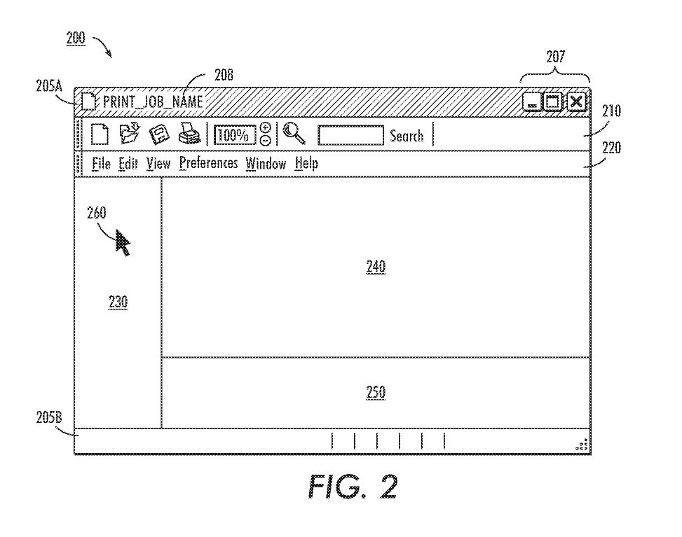

Referring to FIG. 2, illustrated is an exemplary GUI 200, used for displaying relevant color transformation selections for a print job as determined in a pre-flight print job check. Note that the term “GUI” generally refers to a type of environment that represents programs, files, options and so forth by means of graphically displayed icons, menus, and dialog boxes on a computer monitor screen. A user actuates the appropriate keys on the user interface 185 to adjust the parameters of a print job. A user can access and operate the rendering device 190 using the GUI 200. The reasoning system can be a software module such as, for example, the module 111 of apparatus 100 depicted in FIG. 1.

The software module 111, as disclosed herein, is configured to generate a GUI 200 on a display device. For example, the display device may include a cathode ray tube, liquid crystal display, plasma, or other display device. The GUI 200 may provide one or more windows or panes for displaying information to the user. The GUI 200 may be a window-like presentation defined by a top border 205A and bottom border 205B. Typical windows-like controls 207, included minimize, maximize and close functions, may be provided at the upper-right hand corner (or at other locations) of the top border 205. The name of the print job 208 may be displayed at the top of the graphical user interface 200, for example, in the top border 205A. A menu bar 210 and tool bar 220 may be provided just below the top border 205A (or at other locations). The menu bar 210 may include a number of option menus, for example, File options, Edit options, View options, Preferences options, and Window options, and Help options, etc. The tool bar 210 may include a number of features and options, such as shortcut features to create a new file, open a file, save a file, print a file, a zoom feature, a magnification features, and a search feature. Many of features and options of the menu bar 210 and/or tool bar 220 may be conventional and/or customizable to support aspects of the application 100.

A user can interact with the GUI 200 to select and activate such options by pointing and clicking with a user input device such as, for example, a pointing device such as a mouse, and/or with a keyboard. The GUI 200 controls the various display and input/output features of the application and allows a user to interact with the application 100 via a computer's operating system and/or one of more software applications. A pointer 260 may be provided to facilitate user interaction. For example, the user may use a mouse, joystick, light pen, roller-ball, keyboard, or other peripheral devices for manipulating the pointer 260 over the graphical user interface 300. Further, the pointer 260 may permit the user to navigate between the menu bar 210, the tool bar 220, and each of the panes 230, 240, 250 of the graphical user interface 200, as well as to select features and options from among various menus, “pop-up” windows, icons, prompts, etc.

The graphical user interface 200 may include one or more active windows or panes. In one implementation, three primary panes may be provided, including a print job preview pane 230, a relevant color attribute display pane 240, and a grayed-out, irrelevant color attribute display pane 250. These will be discussed in more detail below. Other windows and panes may similarly be provided. Various mechanisms for minimizing, maximizing, moving, and/or changing the dimensions or the individual panes, may be provided as typically found in a windows environment.

In some implementations, the pointer 260 may display location-specific and/or context-specific action menus, in response, for example, to the user hovering or right clicking on a certain pane or location of the graphical user interface 200. The pointer 260 may be, for example, an icon or other indicia, such as an “arrow.” In some implementations, the user may be permitted to change the pointer 260 icon, for example, through the Preferences menu of the menu bar 210. As will be appreciated, the pointer 260 may readily permit other functionality. The pointer 260 may be configured to execute operations, for example, when the user right- or left-clicks a mouse. In some implementations, when the user moves the pointer icon 260 to a different pane or location within the graphical user interface 200, its design and/or functionality may change.

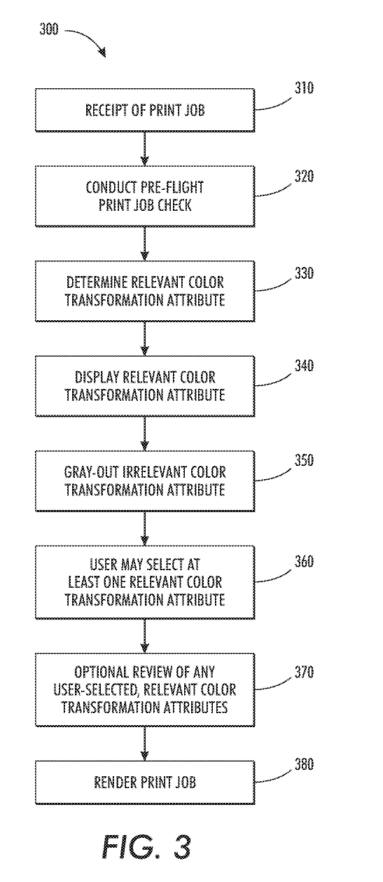

Referring to FIG. 3, illustrated is a block diagram of the overall smart mode color workflow for providing relevant color attributes of a print job for user selection in a color transformation 300. An imaging workflow represents the path of a print job from an image origination input device to an output printing, or output display devices. The smart mode color workflow 300 may begin with receipt of a print job as indicated at block 310. The job receipt may include both capturing an image file and assigning the source device as an input profile.

The workflow continues to conduct a pre-flight print job check as depicted at block 320. The pre-flight check controls the display and user selection of relevant color attributes for a print job. The pre-flight check in a workflow can include, for example: determining the device-dependent color space to be used for a job, determining color profiles that describe all devices employed between input and output devices, such as, for example, CMYK, RGB, spot color, gray, or black, determining color attributes from non-coextensive gamuts, converting an image file to a standard format, setting the image's resolution, or embedding fonts into the image file. Only those relevant color attributes for a print job are displayed for user selection on a GUI 200, as disclosed herein.

The workflow continues with the pre-flight system in the digital front end (DFE) of a color rendering device to determine the relevant color transformation attribute for the print job as illustrated at block 330. Color transformations can occur in different areas, such as, for example, CMYK, RGB, spot color; gray, or black. The workflow then continues with displaying only relevant color attribute selections as described at block 340 in the GUI 210, with such relevant color transformation selections determined in the pre-flight check step indicated at block 330. The relevant print job color attributes are displayed on the GUI 200 in the relevant job attribute display pane 240, as disclosed herein. Only relevant print job attributes or processing selections for that pre-flighted job are presented to the user on the GUI 210 for the user to consider in color transformation of the final rendering as shown at block 340. This presentation of relevant color transformation selections is limited by pre-flight operations. The workflow “grays-out” irrelevant color attributes in the irrelevant color attribute display pane 250 in the GUI 200, as disclosed herein, to prevent a user from selecting that irrelevant color transformation attribute as illustrated at block 350. Displaying only relevant color transformation options for user selection allows a user to make a more informed selection for optimal color quality in the final rendering of a print job.

A user may select at least one of these relevant color transformation attributes as illustrated at block 360. The workflow then applies any user-selected color attributes to the print job to produce optimal color quality in the rendering. The workflow would process and holds and re-rasterizes the print job as the selected color attributes are applied. The workflow continues with an optional review of any user-selected, relevant color transformation attributes as depicted at block 370. In this step, the user can review the displayed print job in the print job preview pane 230 of the GUI 200, as disclosed herein. During review, a user may choose to leave the selected color attributes or further modify based on the pre-flight checks. A pointer 260 would be provided in the GUI 210 for a user to select and modify any color attribute selections. Once the user is satisfied with the selection of color attributes, the workflow continues with rendering the printing the job with any applied, selected color attributes for optimal color quality as indicated at block 380.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A computer-implemented method of enhancing color transformations in color renderings using a smart mode color workflow, said method comprising:
selecting a print job;
performing a print job imaging pre-flight color transformation attribute check of said print job;
determining at least one relevant color transformation attribute for said print job using said print job imaging pre-flight process;
displaying said relevant color transformation attribute for said print job; and
selecting at least one relevant color transformation attribute for said print job to produce optimal color quality in said print job.

2. The method of claim 1 wherein selecting a print job includes inputting said print job into a digital front end of a color rendering device for said pre-flight check.

3. The method of claim 1 wherein determining at least one relevant color transformation attribute for said print job using said print job imaging pre-flight process includes: determining a device-dependent color space to be used for said print job, determining color profiles that describe all devices employed between input and output devices, or determining color attributes from non-coextensive gamuts.

4. The method of claim 1 wherein said color transformation occurs in at least one of the following areas:
CMYK;
RGB;
Spot Color;
Gray; or
Black.

5. The method of claim 1 wherein determining at least one relevant color transformation attribute for said print job using said print job imaging pre-flight process includes: converting an image file to a standard format, setting the image's resolution, or embedding fonts into the image file.

6. The method of claim 1 wherein determining at least one relevant color transformation attribute for said print job using said print job imaging pre-flight check includes said pre-flight check graying out irrelevant color transformation attributes for said print job.

7. The method of claim 1 wherein determining at least one relevant color transformation attribute for said print job using said print job imaging pre-flight process includes said pre-flight check not displaying irrelevant color transformation attributes in a graphical user interface for said print job.

8. The method of claim 1 wherein said relevant color transformation attributes are displayed in a graphical user interface of a data-processing apparatus.

9. The method of claim 1 wherein said selected relevant color transformation attributes are applied to said selected print job to produce optimal color quality for said print job.

10. The method of claim 1 wherein said selected relevant color transformation attributes are applied to said selected print job to produce optimal color quality for a rendered print job.

11. The method of claim 1 wherein said selected relevant color transformation attributes for said print job are reviewed by said user to produce optimal color quality for a print job.

12. A computer-implemented system of enhancing color transformations in color renderings using a smart mode color workflow, comprising:
a data-processing apparatus;
at least one module executed by said data-processing apparatus, said at least one module and said data-processing apparatus being operable in combination with one another to:
select a print job;
perform a print job imaging pre-flight color transformation attribute check of said print job;
determine at least one relevant color transformation attribute for said print job using said print job imaging pre-flight process;
display said relevant color transformation attribute for said print job; and
allow a user to select at least one relevant color transformation attribute for said print job to produce optimal color quality in said print job.

13. The system of claim 12 wherein said at least one module and said data-processing apparatus are further operable in combination with one another to select a print job with a user inputting said print job into a digital front end of a color rendering device for said pre-flight check.

14. The system of claim 12 wherein said at least one module and said data-processing apparatus are further operable in combination with one another to determine a device-dependent color space to be used for said print job, determine color profiles that describe all devices employed between input and output devices, or determine color attributes from non-coextensive gamuts.

15. The system of claim 12 wherein said at least one module and said data-processing apparatus are further operable in combination with one another to convert an image file to a standard format, set an image's resolution, or embedding fonts into said image file.

16. The system of claim 12 wherein said at least one module and said data-processing apparatus are further operable in combination with one another to allow said pre-flight check to gray out irrelevant color transformation attributes on a graphical user interface display for said print job.

17. The system of claim 12 wherein said at least one module and said data-processing apparatus are further operable in combination with one another to allow said pre-flight check to not display irrelevant color transformation attributes on a graphical user interface for said print job.

18. The system of claim 12 wherein said at least one module and said data-processing apparatus are further operable in combination with one another to display relevant color transformation attributes on a graphical user interface of a data-processing apparatus.

19. The system of claim 12 wherein said at least one module and said data-processing apparatus are further operable in combination with one another to apply at least one selected, relevant color transformation attributes to said selected print job to produce optimal color quality for said print job.

20. The system of claim 12 wherein said at least one module and said data-processing apparatus are further operable in combination with one another to apply at least one selected, relevant color transformation attributes to said selected print job to produce optimal color quality for a rendered print job.
